(19) United States
(12) Patent Application Publication
(10) Pub. No.: US 2024/0051064 A1
(43) Pub. Date: Feb. 15, 2024

(54) LASER PROCESSING MACHINE AND MANUFACTURING METHOD OF WAFER

(71) Applicant: DISCO CORPORATION, Tokyo (JP)

(72) Inventor: Ryohei YAMAMOTO, Tokyo (JP)

(21) Appl. No.: 18/360,159

(22) Filed: Jul. 27, 2023

(30) Foreign Application Priority Data
Aug. 10, 2022 (JP) 2022-127997

(51) Int. Cl. B23K 26/08; B23K 26/06

(52) U.S. Cl. CPC B23K 26/083; B23K 26/0665; B23K 26/0604; B23K 2103/56

(57) ABSTRACT

A laser oscillation unit of a laser processing machine for manufacturing a SiC wafer from a SiC ingot includes a seed laser that emits a pulsed laser beam at predetermined pulse intervals, a splitter unit that splits the pulsed laser beam emitted by the seed laser, into at least a first pulsed laser beam and a second pulsed laser beam, a delay unit that delays one of the first pulsed laser beam and the second pulsed laser beam, a merger unit that merges the first pulsed laser beam and the second pulsed laser beam on a downstream side of the delay unit, and an amplifier arranged on a downstream side of the merger unit. A manufacturing method of a SiC wafer from a SiC ingot is also disclosed.

### BACKGROUND OF THE INVENTION

### Field of the Invention

The present invention relates to a laser processing machine for manufacturing a silicon carbide (SiC) wafer from a SiC ingot, and also to a manufacturing method of a SiC wafer from a SiC ingot.

### Description of the Related Art

A silicon (Si) wafer on a front surface of which a plurality of devices such as integrated circuits (ICs) or large-scale integration (LSI) circuits are formed and isolated from each other by a plurality of intersecting scribe lines is divided into individual device chips by a dicing machine or a laser processing machine, and the divided device chips are used in electronic equipment such as mobile phones or personal computers.

As SiC has a band gap approximately three times larger than that of silicon, SiC wafers are used when devices such as power devices or light emitting diodes (LEDs) are formed.

If a conventional wafer manufacturing method is applied to a SiC ingot and the SiC ingot is sliced with an inner-diameter blade to form wafers, however, there is a problem in that only as small as approximately 30% of the ingot is manufactured into SiC wafers, the remaining 70% is discarded, and therefore, such a manufacturing method is not economical (see, for example, JP 2011-84469A).

In the meantime, a manufacturing method of SiC wafers has also been proposed to reduce the amount of the SiC ingot to be discarded (see, for example, JP 2016-111143A). According to this manufacturing method, a pulsed laser beam of a wavelength having transmissivity for a SiC ingot is applied to the SiC ingot, with a focal point of the pulsed laser beam positioned at a depth corresponding to a thickness of the SiC wafers to be manufactured, to form modified layers as separation starting interfaces for separating each SiC wafer from the SiC ingot, and with use of the separation starting interfaces as a boundary, the SiC wafer is separated and manufactured from the SiC ingot.

### SUMMARY OF THE INVENTION

According to the technology described in JP 2016-111143A, it is possible to reduce the amount of SiC which is to be discarded, compared with the case in which SiC wafers are manufactured from a SiC ingot with use of an inner-diameter blade. If SiC wafers are each manufactured using, as separation starting interfaces, modified layers formed with the focal point of the pulsed laser beam positioned inside the SiC ingot, however, a need arises to perform grinding and lapping processing to remove the modified layers formed with the focal point of the pulsed laser beam positioned inside the SiC ingot. The productivity is hence poor, and moreover, there is still a lot of portions to be discarded, leading to an outstanding demand for further improvements.

The present invention therefore has as objects thereof the provision of a laser processing machine and a wafer manufacturing method which can improve the productivity when manufacturing SiC wafers from a SiC ingot and can reduce the amount of SiC to be discarded.

In accordance with a first aspect of the present invention, there is provided a laser processing machine for manufacturing a SiC wafer from a SiC ingot. The laser processing machine includes a holding table that holds the SiC ingot, and a laser irradiation unit that applies, to the SiC ingot held on the holding table, a pulsed laser beam of a wavelength having transmissivity for the SiC ingot. The laser irradiation unit includes a laser oscillation unit that emits the pulsed laser beam, and a condenser that applies the pulsed laser beam emitted from the laser oscillation unit, with a focal point of the pulsed laser beam positioned at a depth which corresponds to a thickness of the SiC wafer to be manufactured, from an end face of the SiC ingot. The laser oscillation unit includes a seed laser that emits the pulsed laser beam at predetermined pulse intervals, a splitter unit that splits the pulsed laser beam emitted by the seed laser, into at least a first pulsed laser beam and a second pulsed laser beam, a delay unit that delays one of the first pulsed laser beam and the second pulsed laser beam, a merger unit that merges the first pulsed laser beam and the second pulsed laser beam on a downstream side of the delay unit, and an amplifier arranged on a downstream side of the merger unit. The pulsed laser beam emitted by the seed laser is suppressed in a peak of energy per pulse owing to the delay of the one of the first pulsed laser beam and the second pulsed laser beam, and SiC is dissociated into Si and C to form a separation layer.

In accordance with a second aspect of the present invention, there is provided a method of manufacturing a SiC wafer from a SiC ingot. The manufacturing method includes a pulsed laser beam irradiation step of holding the SiC ingot on a holding table, emitting a pulsed laser beam of a wavelength having transmissivity for the SiC ingot, from a laser oscillation unit, and applying, to the SiC ingot held on the holding table, the pulsed laser beam with a focal point of the pulsed laser beam positioned at a depth which corresponds to a thickness of the SiC wafer to be manufactured, from an end face of the SiC ingot to form a separation layer, and a wafer separating step of separating the SiC wafer from the SiC ingot. The laser oscillation unit includes a seed laser that emits the pulsed laser beam at predetermined pulse intervals, a splitter unit that splits the pulsed laser beam emitted by the seed laser, into at least a first pulsed laser beam and a second pulsed laser beam, a delay unit that delays one of the first pulsed laser beam and the second pulsed laser beam, a merger unit that merges the first pulsed laser beam and the second pulsed laser beam on a downstream side of the delay unit, and an amplifier arranged on a downstream side of the merger unit. The pulsed laser beam emitted by the seed laser is suppressed in a peak of energy per pulse owing to the delay of the one of the first pulsed laser beam and the second pulsed laser beam, and SiC is dissociated into Si and C to form a separation layer.

Assuming that a direction orthogonal to a direction in which a C-plane is inclined with respect to the end face of the SiC ingot and an off-angle is formed is an X-axis and a direction orthogonal to the X-axis is a Y-axis, the pulsed laser beam irradiation step may preferably include a separation zone forming substep of applying, to the SiC ingot held on the holding table, the pulsed laser beam with the focal point of the pulsed laser beam positioned at the depth which corresponds to the thickness of the SiC wafer to be manufactured, while feeding the SiC ingot for processing in an X-axis direction, thereby forming a strip-shaped separation zone with cracks propagating, along the C-plane, from each of modified regions where SiC has been dissociated into Si and C, an indexing feed substep of feeding the focal point of the pulsed laser beam for indexing in a Y-axis direction such that another strip-shaped separation zone is arranged side by side with the former strip-shaped separation zone with a predetermined interval in the Y-axis direction therebetween, and repeatedly conducting the separation zone forming substep and the indexing feed substep to form a separation layer formed from a plurality of adjacent strip-shaped separation zones.

According to the laser processing machine of the present invention, the pulsed laser beam is suppressed in the peak of energy per pulse, compared with a configuration in which the pulsed laser beam is applied without being split and delayed. Therefore, SiC can appropriately be dissociated into Si and C, and an appropriate separation layer can also be formed without much damage.

According to the wafer manufacturing method of the present invention, the pulsed laser beam is suppressed in the peak of energy per pulse owing to the delay of the one of the first pulsed laser beam and the second pulsed laser beam, compared with a case in which the pulsed laser beam is applied without being split and delayed. It is therefore possible to appropriately dissociate SiC into Si and C, and also to form an appropriate separation layer without much damage.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is an overall perspective view of a laser processing machine according to an embodiment of the first aspect of the present invention;

FIG. 2A is a plan view of an example of a SiC ingot to be processed by the laser processing machine of FIG. 1 for manufacturing a SiC wafer;

FIG. 2B is a side view of the SiC ingot exemplified in FIG. 2A;

FIG. 3A is a block diagram schematically illustrating an outline of an optical system of a laser irradiation unit arranged in the laser processing machine illustrated in FIG. 1;

FIG. 3B is a concept diagram illustrating a pulse waveform of a pulsed laser beam produced by a merger unit in the laser irradiation unit illustrated in FIG. 3A;

FIG. 4A is a perspective view illustrating an example of a pulsed laser beam irradiation step in a wafer manufacturing method according to an embodiment of the second aspect of the present invention;

FIG. 4B is a fragmentary cross-sectional view of the wafer, and illustrates how the pulsed laser beam irradiation step is performed; and

FIG. 5 is a perspective view illustrating an example of a wafer separating step in the wafer manufacturing method of FIG. 4A.

### DETAILED DESCRIPTION OF THE PREFERRED EMBODIMENTS

A laser processing machine according to an embodiment of the first aspect of the present invention and a wafer manufacturing method according to an embodiment of the second aspect of the present invention will hereinafter be described in detail with reference to the attached drawings.

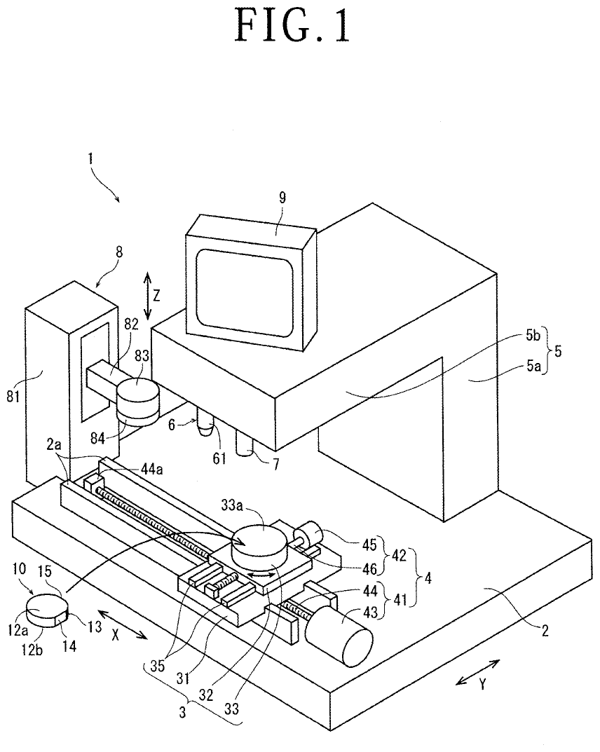

FIG. 1 illustrates an overall perspective view of a laser processing machine 1 according to the present embodiment, which can perform the wafer manufacturing method according to the present embodiment. The laser processing machine 1 includes at least a holding unit 3 that holds a SiC ingot 10 such as that illustrated in FIG. 1 and a laser irradiation unit 6 that applies, to the SiC ingot 10 held on the holding unit 3, a pulsed laser beam of a wavelength having transmissivity for the SiC ingot 10.

The laser processing machine 1 is provided with a stationary bed 2 on which the holding unit 3 and the laser irradiation unit 6 are arranged, and further includes a moving mechanism 4 that moves the holding unit 3 in an X-axis direction and in a Y-axis direction orthogonal to the X-axis direction, an imaging unit 7 for performing an alignment, a wafer separation unit 8, and a display unit 9.

The holding unit 3 includes, as illustrated in FIG. 1, a rectangular X-axis direction movable plate 31 that is mounted movably in the X-axis direction on the bed 2, a rectangular Y-axis direction movable plate 32 that is mounted movably in the Y-axis direction on the X-axis direction movable plate 31, and a holding table 33 that is arranged on the Y-axis direction movable plate 32, is configured to be rotatable owing to inclusion of a pulse motor inside, and has a planar holding surface 33a.

The moving mechanism 4 includes an X-axis moving mechanism 41 that moves the holding table 33 in the X-axis direction and a Y-axis moving mechanism 42 that moves the holding table 33 in the Y-axis direction. The X-axis moving mechanism 41 converts rotary motion of a motor 43 into linear motion via a ball screw 44 supported at an end portion thereof on a bearing block 44a, and transmits the linear motion to the X-axis direction movable plate 31. The X-axis direction movable plate 31 is moved in the X-axis direction along a pair of guide rails 2a and 2a arranged along the X-axis direction on the bed 2. The Y-axis moving mechanism 42 converts rotary motion of a motor 45 into linear motion via a ball screw 46, transmits the linear motion to the Y-axis direction movable plate 32, and moves the Y-axis direction movable plate 32 in the Y-axis direction along a pair of guide rails 35 and 35 arranged along the Y-axis direction on the X-axis direction movable plate 31.

The laser processing machine 1 includes a column 5 constructed of a vertical base portion 5a, which is disposed upright on the bed 2 at a location lateral of the X-axis moving mechanism 41 and the Y-axis moving mechanism 42, and a horizontal head portion 5b, which extends in a horizontal direction from an upper end portion of the vertical base portion 5a. Inside the horizontal head portion 5b of the column 5, an optical system, which makes up the above-described laser irradiation unit 6, and the imaging unit 7 are accommodated.

The wafer separation unit 8 in the present embodiment is arranged on the bed 2, and is disposed in a vicinity of terminal end portions of the above-described guide rails 2a and 2a (on a side of the bearing block 44a). The wafer separation unit 8 includes a separation unit casing 81, a separation unit arm 82 accommodated at a portion thereof in the separation unit casing 81 and supported movably up and down in a Z-axis direction (up-down direction), a separation pulse motor 83 arranged on a distal end portion of the separation unit arm 82, and a drawing unit 84 that is supported rotatably by the separation pulse motor 83 on a lower portion of the separation pulse motor 83 and that includes a plurality of suction holes in a lower surface thereof. In the separation unit casing 81, a Z-axis moving mechanism, free of illustration, is included to move the separation unit arm 82 under control in the Z-axis direction. The separation unit casing 81 is provided with a Z-axis direction position detector unit (not illustrated) to detect the position in the Z-axis direction of the separation unit arm 82, and a signal indicating the position of the separation unit arm 82 is sent to a controller (not illustrated) that is to be described hereinafter.

The controller is configured with a computer, and includes a central processing unit (CPU) that performs computation processing according to a control program, a read only memory (ROM) that stores the control program and the like, a random access memory (RAM) that enables writing of detection values detected, computation results, and the like for temporary storage and their reading, an input interface, and an output interface (illustration of details is omitted). In addition to the above-described laser irradiation unit 6, the imaging unit 7, the X-axis moving mechanism 41, the Y-axis moving mechanism 42, the wafer separation unit 8, the display unit 9, and the like are also connected to and controlled by the controller.

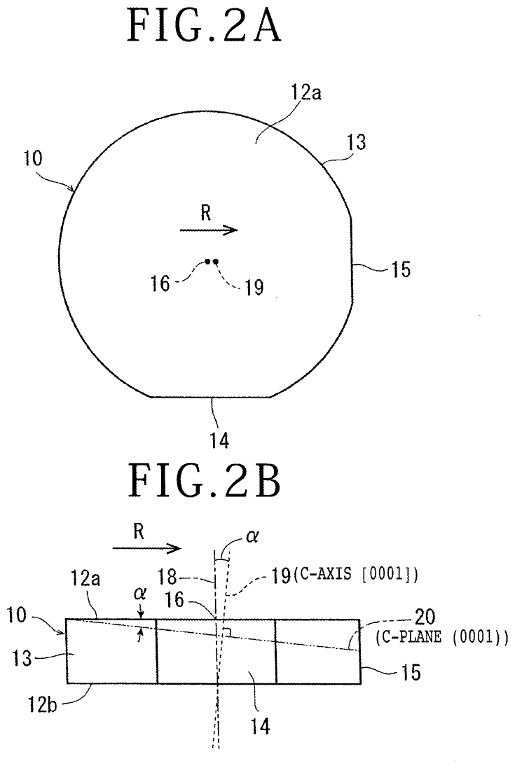

In FIG. 1 and further in FIGS. 2A and 2B, an example of the SiC ingot 10 to be processed by the above-described laser processing machine 1 for the manufacture of a SiC wafer is illustrated. The illustrated SiC ingot 10 illustrates a state before a below-mentioned separation layer is formed. The SiC ingot 10 is formed from hexagonal single crystal SiC, and is formed as a whole in a substantially cylindrical shape. The SiC ingot 10 has a circular first end face 12a (upper surface), a circular second end face 12b (lower surface) that is on a side opposite to the first end face 12a and is to be placed on the holding surface 33a of the above-described holding table 33, a peripheral surface 13 located between the first end face 12a and the second end face 12b, a C-axis 19 ([0001] orientation) extending from the first end face 12a to the second end face 12b, and a C-plane 20 ((0001) plane) orthogonal to the C-axis 19. In the illustrated SiC ingot 10, the C-axis 19 is inclined as indicated by “a” in the figure with respect to a perpendicular 18 passing through a center 16 of the first end face 12a illustrated in FIG. 2A (see FIG. 2B). An off-angle α (for example, α=1, 3, or 6 degrees) is formed between the C-plane 20 and the first end face 12a.

The direction in which the off-angle α is formed is indicated by an arrow R in FIGS. 2A and 2B. In the peripheral surface 13 of the SiC ingot 10, rectangular first orientation flat 14 and second orientation flat 15 are formed to indicate crystal orientations. The first orientation flat 14 is parallel to a direction R in which the off-angle α is formed, and the second orientation flat 15 is orthogonal to the direction R in which the off-angle α is formed. The second orientation flat 15 has a length set shorter than that of the first orientation flat 14, the front and back of the SiC ingot 10 and the direction of the inclination of the off-angle α are thereby specified.

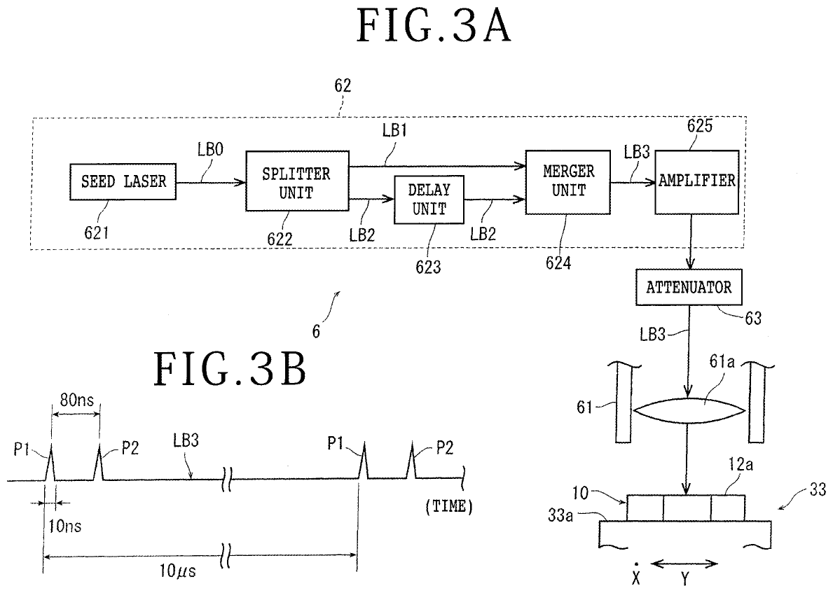

With reference to FIG. 3A, a description will be made with regard to the optical system of the laser irradiation unit 6, which is suited for manufacturing the SiC wafer by performing laser processing on the above-described SiC ingot 10.

As illustrated in FIG. 3A, the laser irradiation unit 6 is configured with at least a laser oscillation unit 62 that emits the pulsed laser beam and a condenser 61 that applies the pulsed laser beam emitted from the laser oscillation unit 62, to the SiC ingot held on the holding table 33, from an end face (the first end face 12a in the present embodiment) of the SiC ingot 10 with a focal point of the pulsed laser beam positioned at a depth corresponding to a thickness of the wafer to be manufactured.

The laser oscillation unit 62 includes a seed laser (which may also be called a “seeder”) 621 that emits a pulsed laser beam LB0 at predetermined pulse intervals, a splitter unit 622 that splits the pulsed laser beam LB0 emitted by the seeder 621, into at least a first pulsed laser beam LB1 and a second pulsed laser beam LB2, a delay unit 623 that delays one of the first pulsed laser beam LB1 and the second pulsed laser beam LB2 (the second pulsed laser beam LB2 in the present embodiment), a merger unit 624 that merges the first pulsed laser beam LB1 and the second pulsed laser beam LB2 on a downstream side of the delay unit 623 to produce a pulsed laser beam LB3, and an amplifier 625 that is arranged on a downstream side of the merger unit 624 and modifies the pulsed laser beam LB3. The splitter unit 622 and the merger unit 624 are each configured, for example, with a fiber coupler. The delay unit 623 is configured with an optical fiber, and adopts, as this optical fiber, an optical fiber having, for example, a refractive index of 1.5 and a length of 48 m to set a below-mentioned delay time at 80 ns. The pulsed laser beam LB3 emitted from the laser oscillation unit 62 configured as described above has already been processed into the pulsed laser beam LB3 having such a pulse waveform as illustrated in FIG. 3B (in which the abscissa represents time, and the ordinate represents energy), is adjusted in power by an attenuator 63 and condensed through a condenser lens 61a of the condenser 61, and is then applied to the first end face 12a of the SiC ingot 10.

In the present embodiment, the second pulsed laser beam LB2 is delayed by the delay unit 623 as described above, but the first pulsed laser beam LB1 may be delayed instead. The predetermined pulse intervals of the pulsed laser beam LB0 that the seed laser 621 emits in the present embodiment are 10 μs, and its pulse width is 10 nm. The pulsed laser beam LB3 generated by the laser oscillation unit 62 is applied including pulses P1 of the first pulsed laser beam LB1 and pulses P2 of the second pulsed laser beam LB2, the pulses P2 being delayed relative to the pulses P1 by the action of the delay unit 623, as illustrated in FIG. 3B.

The laser processing machine 1 of the present embodiment generally has the configuration as described above, and the wafer manufacturing method of the present embodiment, which is performed using the laser processing machine 1, will be described hereinafter.

When the manufacturing method of the present embodiment is performed, the SiC ingot 10 that has a predetermined thickness sufficient to manufacture a plurality of SiC wafers is first provided, and the SiC ingot 10 is fixed on the holding table 33 with an adhesive (for example, an epoxy resin based adhesive) interposed between the second end face 12b (lower surface) of the SiC ingot 10 and the holding surface 33a of the holding table 33 of the laser processing machine 1. Then, the above-described moving mechanism 4 is actuated to move the holding table 33 to below the imaging unit 7, and the SiC ingot 10 is imaged by the imaging unit 7.

Next, a pulsed laser beam irradiation step is performed. More specifically, the pulsed laser beam LB3 of the wavelength having transmissivity for the SiC ingot 10 is applied from the first end face 12a of the SiC ingot 10 with a focal point FP of the pulsed laser beam LB3 positioned at the depth corresponding to the thickness of the SiC wafer to be manufactured, and a separation layer is thereby formed. The pulsed laser beam irradiation step in the present embodiment includes a separation zone forming substep and an indexing feed substep, which will hereinafter be described.

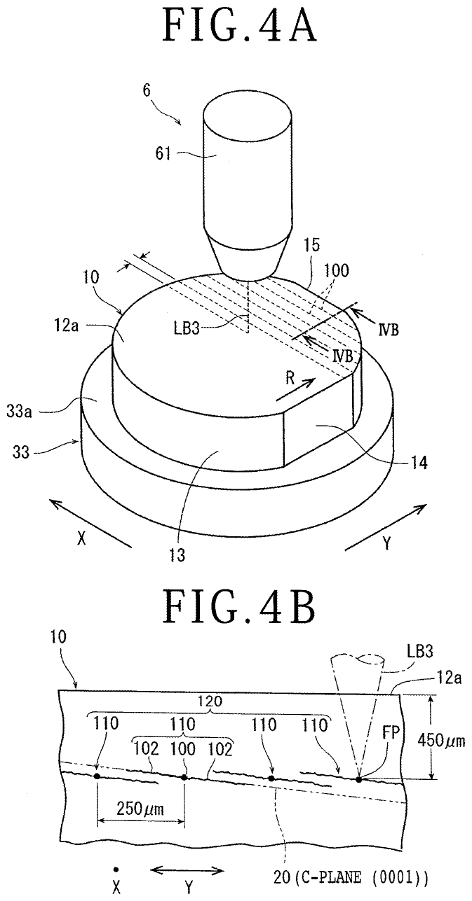

When the pulsed laser beam irradiation step is performed, the moving mechanism 4 is first actuated on the basis of the image of the SiC ingot 10 as captured by the imaging unit 7, so that the holding table 33 is moved and rotated to adjust the direction of the SiC ingot 10 to a predetermined direction and also adjust the positions in an XY plane of the SiC ingot 10 and condenser 61. When the direction of the SiC ingot 10 is adjusted to the predetermined direction, the first orientation flat 14 and the second orientation flat 15 are aligned to the Y-axis direction and the X-axis direction, respectively, as illustrated in FIG. 4A. As a consequence, the direction R in which the off-angle α is formed is aligned to the Y-axis direction, and further, the direction orthogonal to the direction R in which the off-angle α is formed is aligned to the X-axis direction.

The condenser 61 is next lifted or lowered by a focal point position adjustment mechanism, free of illustration, and as appreciated from FIG. 4B as an IVB-IVB cross-section of FIG. 4A, the focal point FP is positioned at the depth corresponding to the thickness of the wafer to be manufactured. In the present embodiment, the depth is set at a depth of 450 μm from the first end face 12a. The X-axis moving mechanism 41 of the moving mechanism 4 is then actuated. While the SiC ingot 10 is fed for processing in the X-axis direction aligned to the direction orthogonal to the direction R in which the off-angle α is formed, the pulsed laser beam LB3 of the wavelength having transmissivity for SiC is applied from the condenser 61 to the SiC ingot 10. At this time, SiC is dissociated into silicon (Si) and carbon (C) at the position of the focal point FP by the application of the pulsed laser beam LB3, and the pulsed laser beam LB3 applied next is absorbed in the C formed before. Accordingly, SiC is dissociated into Si and C in a chain to form modified regions 100, and cracks 102 extend on both sides of each of the modified regions 100 and propagate from each of the modified regions 100 along the C-plane. As a result, by each of the modified regions 100 and the cracks 102, a strip-shaped separation zone 110 is formed extending in the X-axis direction (separation zone forming substep).

After the separation zone forming substep has been performed, the Y-axis moving mechanism 42 of the moving mechanism 4 is actuated to feed the focal point FP of the pulsed laser beam LB3 for indexing by a predetermined index amount (250 μm in the present embodiment) in the Y-axis direction such that another strip-shaped separation zone 110 is arranged side by side with the former strip-shaped separation zone 110 with a predetermined interval in the Y-axis direction therebetween. After the indexing feed substep has been performed as described above, the above-described separation zone forming substep is performed to form a further separation zone 110 adjacent to the separation zone 110 formed before by performing the above-described separation zone forming substep. A separation layer 120 formed of a plurality of adjacent separation zones 110 is formed by repeatedly and alternately performing the separation zone forming substep and the indexing feed substep over the entirety of the first end face 12a of the SiC ingot 10.

It is to be noted that, when the above-described pulsed laser beam irradiation step is performed, laser processing conditions are set, for example, as follows.
Wavelength: 1,064 nm
Repetition frequency: 100 kHz
Pulse width: 10 ns
Delay time: 30 to 100 ns
Average power: 4 W
Energy per pulse unless spit=0.00004 (J)
Numerical aperture (NA) of condenser lens: 0.7
Spot size: 6.7 μm
Processing feed rate: 50 to 135 mm/s
Position (depth) of separation layer: 450 μm
Index amount: 250 μm

In the pulsed laser beam irradiation step described above, as illustrated in FIG. 3B, each pulse generated by the seed laser 621 is split into the pulse P1 formed by the first pulsed laser beam LB1 and the pulse P2 formed by the second pulsed laser beam LB2, and one of these pulses P1 and P2, specifically, the pulse P2, is applied with a delay time caused by the delay unit 623. Here, the delay time is set to cause a slight delay time such that the pulse P2 formed by the second pulsed laser beam LB2 is applied while energy (heat) by the pulse P1 formed by the first pulsed laser beam LB1 still remains in the SiC ingot 10, and is set, for example, at 30 to 100 ns. As a consequence, the peak of energy per pulse is suppressed compared with a case in which, unlike the present embodiment, each pulse generated by the seed laser 621 is applied as a single pulse without being split, effects of leak light in a depth direction are suppressed, SiC is appropriately dissociated into Si and C, the modified regions 100 and the cracks 102 are appropriately formed in the direction of the C-plane, and the separation layer 120 is appropriately formed without much damage.

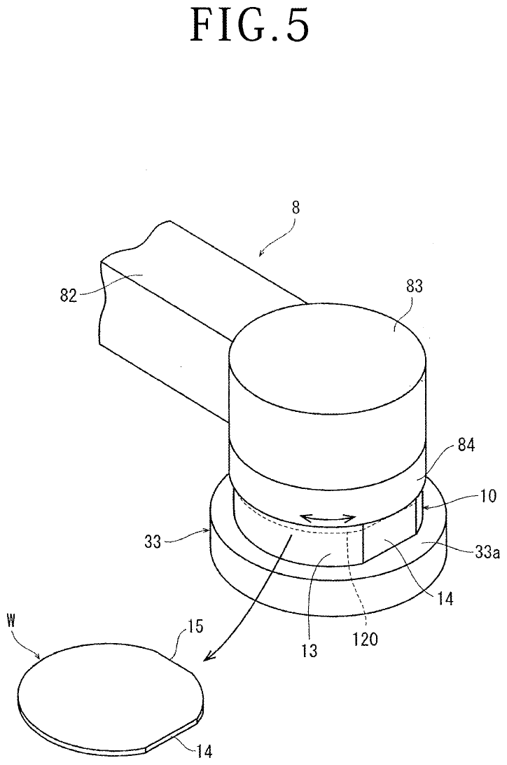

After the separation layer 120 has been formed through the above-described pulsed laser beam irradiation step, a wafer separating step is performed to separate a SiC wafer W (see FIG. 5) from the SiC ingot 10 by using the separation layer 120 as separation starting interfaces.

When the wafer separating step is performed, the above-described moving mechanism 4 is first actuated to position the holding table 33 below the drawing unit 84 of the wafer separation unit 8. The separation unit arm 82 is then lowered by the Z-axis moving mechanism, free of illustration, and as illustrated in FIG. 5, the drawing unit 84 is brought at a lower surface thereof into close contact with the SiC ingot 10, and the SiC ingot 10 is drawn to the lower surface of the drawing unit 84. An ultrasonic vibration imparting unit, free of illustration, is then actuated to impart ultrasonic vibrations to the lower surface of the drawing unit 84, and at the same time, the drawing unit 84 is repeatedly rotated clockwise and counterclockwise by the separation pulse motor 83. As a consequence, the SiC wafer W can be separated using, as the separation starting interfaces, the separation layer 120 formed in the SiC ingot 10. After the SiC wafer W has been separated from the SiC ingot 10, an upper surface (a fresh first end face 12a) of the SiC ingot 10 is lapped, and after that, the above-described pulsed laser beam irradiation step and wafer separating step are repeated, so that a plurality of SiC wafers W can be formed. Each SiC wafer W separated from the SiC ingot 10 is also lapped at a separated surface thereof as needed, thereby manufacturing a SiC wafer W on one of surfaces of which devices can be formed.

As described above, in the pulsed laser beam irradiation step in the present embodiment, the peak of energy per pulse is suppressed by the action of the laser oscillation unit 62, SiC is appropriately dissociated into Si and C, and the separation layer 120 is formed without much damage. It is therefore possible to reduce the stock removal when the fresh first end face 12a of the SiC ingot 10 after the separation and the separated surface (on the side of the lower surface) of the SiC wafer W separated and acquired are lapped, and hence to reduce the amount of SiC to be discarded from the SiC ingot 10. As a result, the production efficiency is improved, and moreover, the number of SiC wafers to be produced from a SiC ingot of the same thickness can be increased.

It is to be noted that the present invention is not limited to use when acquiring a plurality of SiC wafers from such a large-thickness SiC ingot as that described above. For example, the present invention encompasses such cases where, by applying the present invention to a thin SiC substrate of approximately 1 mm thickness as an ingot and performing the above-described manufacturing method, a separation layer is formed centrally in a thickness direction to manufacture two SiC wafers.

Further, the present invention is not limited to splitting the pulsed laser beam LB0 emitted by the seed laser 621, into only the first pulsed laser beam LB1 and the second pulsed laser beam LB2 as described above, and may be configured such that the pulsed laser beam LB0 is split into three or more pulsed laser beams and three or more pulses may be continuously and repeatedly applied with predetermined delay times.

In the embodiment described above, the separation layer 120 formed from the adjacent strip-shaped separation zones 110 is configured to be formed by assuming that the direction orthogonal to the direction in which the C-plane is inclined with respect to the first end face 12a of the SiC ingot 10 and the off-angle α is formed is the X-axis and the direction orthogonal to the X-axis is the Y-axis, repeating the separation zone forming substep of applying the pulsed laser beam LB3 to the SiC ingot 10 with the focal point FP of the pulsed laser beam LB3 positioned at the depth which corresponds to the thickness of the SiC wafer to be manufactured, while feeding the SiC ingot for processing in the X-axis direction, thereby forming the strip-shaped separation zone 110 with the cracks 102 propagating, along the C-plane, from each of modified regions 100 where SiC has been dissociated into Si and C and the indexing feed substep of feeding the focal point FP of the pulsed laser beam LB3 for indexing in the Y-axis direction such that the additional strip-shaped separation zone 110 is arranged side by side with the former strip-shaped separation zone 110 with the predetermined interval in the Y-axis direction therebetween. However, the present invention is not limited to the foregoing, and a separation layer may also be formed, for example, by spirally applying the pulsed laser beam LB3 to the SiC ingot 10 or dispersing the pulsed laser beam LB3 at random and evenly applying it to the SiC ingot 10. However, by applying the pulsed laser beam LB3 as in the embodiment described with reference to FIGS. 4A and 4B, the separation zones 110 and the separation layer 120 can be formed more appropriately. It is therefore more preferred to apply the pulsed laser beam LB3 as in the embodiment.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laser processing machine for manufacturing a SiC wafer from a SiC ingot, the laser processing machine comprising:
a holding table that holds the SiC ingot; and
a laser irradiation unit that applies, to the SiC ingot held on the holding table, a pulsed laser beam of a wavelength having transmissivity for the SiC ingot,
wherein the laser irradiation unit includes
a laser oscillation unit that emits the pulsed laser beam, and
a condenser that applies the pulsed laser beam emitted from the laser oscillation unit, with a focal point of the pulsed laser beam positioned at a depth which corresponds to a thickness of the SiC wafer to be manufactured, from an end face of the SiC ingot,
the laser oscillation unit includes
a seed laser that emits the pulsed laser beam at predetermined pulse intervals,
a splitter unit that splits the pulsed laser beam emitted by the seed laser, into at least a first pulsed laser beam and a second pulsed laser beam,
a delay unit that delays one of the first pulsed laser beam and the second pulsed laser beam,
a merger unit that merges the first pulsed laser beam and the second pulsed laser beam on a downstream side of the delay unit, and
an amplifier arranged on a downstream side of the merger unit, and
the pulsed laser beam emitted by the seed laser is suppressed in a peak of energy per pulse owing to the delay of the one of the first pulsed laser beam and the second pulsed laser beam, and SiC is dissociated into Si and C to form a separation layer.

2. A method of manufacturing a SiC wafer from a SiC ingot, the method comprising:
a pulsed laser beam irradiation step of holding the SiC ingot on a holding table, emitting a pulsed laser beam of a wavelength having transmissivity for the SiC ingot, from a laser oscillation unit, and applying, to the SiC ingot held on the holding table, the pulsed laser beam with a focal point of the pulsed laser beam positioned at a depth which corresponds to a thickness of the SiC wafer to be manufactured, from an end face of the SiC ingot to form a separation layer; and
a wafer separating step of separating the SiC wafer from the SiC ingot,
wherein the laser oscillation unit includes
a seed laser that emits the pulsed laser beam at predetermined pulse intervals,
a splitter unit that splits the pulsed laser beam emitted by the seed laser, into at least a first pulsed laser beam and a second pulsed laser beam,
a delay unit that delays one of the first pulsed laser beam and the second pulsed laser beam,
a merger unit that merges the first pulsed laser beam and the second pulsed laser beam on a downstream side of the delay unit, and
an amplifier arranged on a downstream side of the merger unit, and
the pulsed laser beam emitted by the seed laser is suppressed in a peak of energy per pulse owing to the delay of the one of the first pulsed laser beam and the second pulsed laser beam, and SiC is dissociated into Si and C to form a separation layer.

3. The manufacturing method according to claim 2,
wherein, assuming that a direction orthogonal to a direction in which a C-plane is inclined with respect to the end face of the SiC ingot and an off-angle is formed is an X-axis and a direction orthogonal to the X-axis is a Y-axis, the pulsed laser beam irradiation step includes
a separation zone forming substep of applying, to the SiC ingot held on the holding table, the pulsed laser beam with the focal point of the pulsed laser beam positioned at the depth which corresponds to the thickness of the SiC wafer to be manufactured, while feeding the SiC ingot for processing in an X-axis direction, thereby forming a strip-shaped separation zone with cracks propagating, along the C-plane, from each of modified regions where SiC has been dissociated into Si and C,
an indexing feed substep of feeding the focal point of the pulsed laser beam for indexing in a Y-axis direction such that another strip-shaped separation zone is arranged side by side with the former strip-shaped separation zone with a predetermined interval in the Y-axis direction therebetween, and
repeatedly conducting the separation zone forming substep and the indexing feed substep to form a separation layer formed from a plurality of adjacent strip-shaped separation zones.
